(19) United States
(12) Patent Application Publication
(10) Pub. No.: US 2007/0170494 A1
(43) Pub. Date: Jul. 26, 2007

(54) Nonvolatile memory device and method for fabricating the same

(75) Inventors: Dong-Gun Park, Seongnam-si (KR); Sung-Min Kim, Bupyeong-gu (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/584,965

(22) Filed: Oct. 23, 2006

(30) Foreign Application Priority Data
Oct. 24, 2005 (KR) 10-2005-0100404

(51) Int. Cl. H01L 29/788; H01L 21/336

(52) U.S. Cl. 257/316; 257/321; 257/322; 438/264; 438/266

(57) ABSTRACT

In a nonvolatile memory device, and a method for fabricating the nonvolatile memory device, two floating gates are formed so as to be isolated from each other in a single memory cell field. The method is comprised of forming a first conductive layer pattern to have pattern portions that are separated from each other, removing a central part of the first conductive layer pattern portions, and forming first and second floating gates that are separated from each other, A second conductive layer is formed on the first and second floating gates, and a dielectric layer is interposed between the first and second floating gates and the second conductive layer. The operational reliability of the nonvolatile memory device is thereby improved.

### CROSS-REFERENCE TO RELATED APPLICATIONS

This U.S. non-provisional patent application claims priority under 35 U.S.C. § 119 to Korean Patent Application 2005-100404 filed on Oct. 24, 2005, the contents of which are herein incorporated by reference in their entirety.

### BACKGROUND OF THE INVENTION

1. Field of the Invention

The subject matter described herein is concerned with semiconductor devices, which in particular relates to nonvolatile memory devices and methods for fabricating the same.

2. Description of the Related Art

Semiconductor memory devices can generally be classified into volatile and nonvolatile types. Volatile memory devices, e.g., dynamic and static random access memory devices, are operable at high data input/output rates, but lose stored data when a supply of power is suspended. Nonvolatile memory devices retain their data even without the application of the power supply.

Flash memory devices are nonvolatile memories, which are fabricated in high integration density with merits taken from erasable-programmable read only memories (EPROMs) and electrical EPROMs. Flash memories can generally be classified as floating-gate and floating-trap types in accordance with the types of data storage layers that constitute their unit cells, or can be classified as stacked and split-gate types in accordance with the types of unit cell structures. A cell gate structure of the stacked flash memory device is commonly configured in an architecture whereby floating and control gates are stacked with a gate interlayer dielectric layer interposed between them.

FIG. 1 is a sectional view showing a general cell gate structure in a stacked flash memory device among nonvolatile memory units.

As shown in FIG. 1, on a substrate 10 are disposed a cell gate 29 in which a tunnel oxide layer 21, a floating gate 23, a gate interlayer dielectric layer 25, and a control gate 27 are stacked. Source and drain regions 11 and 13 are positioned at both sides of the cell gate 29.

In a NOR-type flash memory device, electrons are accumulated in the floating gate 23 by way of hot electron injection during a program operation, while electrons are discharged from the floating gate 23 into the source region 11 by way of Fowler-Nordheim (F-N) tunneling effect during an erase operation. In a NAND-type flash memory device, program and erase operations are accomplished both by the F-N tunneling effect.

During a read operation, both the NOR and NAND-type flash memory devices determine whether electrons have been accumulated in the floating gate 23, i.e., the presence of data storage, by discerning whether there is current flow from the drain region 13 toward the source region 11. As such, the flash memory device is variable in threshold voltage according to the amount of charge stored in the floating gate, and differentiates the data of memory cells by sensing variation in the cell currents in accordance with a difference in threshold voltages.

With the continued reduction of design rule, a leakage of charge from the floating gate toward the source and drain regions can be generated for various reasons such as a reduction in size of the floating gate. This, in turn, can cause the threshold voltage of memory cells to fluctuate, which can cause read failures, degrading operational reliability of the nonvolatile memory device.

### SUMMARY OF THE INVENTION

Embodiments of the present invention are directed to addressing the aforementioned limitations of the conventional devices, providing a nonvolatile memory device with high operational reliability and a method for fabricating the same.

In one aspect, the present invention is directed to a method for fabricating a nonvolatile memory device, comprising: forming a first conductive layer on an active region between field isolation layers in a substrate, a tunnel oxide layer being interposed between the substrate and the first conductive layer, extending along a first direction; forming a hard mask pattern that intersects the first conductive layer on the substrate and extends along a second direction; forming a first conductive layer pattern having pattern portions that are separated from each other in the first direction using the hard mask pattern as an etch mask; removing a central part of the first conductive layer pattern portions to form first and second floating gates that are separated from each other in the first direction; and forming a second conductive layer on the first and second floating gates, a dielectric layer being interposed between the first and second floating gates and the second conductive layer.

In one embodiment, forming the first and second floating gates comprises: forming an interlayer insulation layer on the substrate including the first conductive layer pattern and planarizing the interlayer insulation layer to expose an top face of the hard mask pattern; removing the hard mask pattern to expose an top face of the first conductive layer pattern and sidewalls of the interlayer insulation layer; forming spacers on the exposed sidewalls of the interlayer insulation layer; and etching the first conductive layer pattern by using the spacers as an etch mask.

In another embodiment, the interlayer insulation layer is formed of a material having an etch selectivity with respect to the hard mask pattern.

In another embodiment, forming the second conductive layer comprises: forming a first insulation layer to fill a space between the first and second floating gates; forming the dielectric layer on the first and second floating gates and the first insulation layer; and forming the second conductive layer on the dielectric layer.

In another embodiment, the method further comprises, before forming the first insulation layer, forming a second insulation layer on sides of the first and second floating gates facing each other.

In another embodiment, the method further comprises, before forming the first insulation layer: etching the tunnel oxide layer between the first and second floating gates to expose the substrate; and forming a second insulation layer on the exposed substrate and the sides of the first and second floating gates facing each other.

In another embodiment, forming the first insulation layer is performed by forming a silicon nitride layer between the first and second floating gates and etching the silicon nitride layer and the spacers to top faces of the first and second floating gates.

In another embodiment, forming the first and second floating gates comprises: etching the hard mask pattern to reduce a width of the hard mask pattern down in width and exposing a part of a top face of the first conductive layer pattern at both sides of the hard mask pattern; forming and flattening an interlayer insulation layer on the substrate to expose a top face of the reduced-width hard mask pattern; removing the reduced-width hard mask pattern to expose a top face of the first conductive layer pattern; and etching the first conductive layer pattern by using the interlayer insulation layer as an etch mask.

In another embodiment, the interlayer insulation layer is formed of a material having an etch selectivity with respect to the hard mask pattern.

In another embodiment, forming the second conductive layer comprises: forming a first insulation layer to fill a space between the first and second floating gates; exposing top faces of the first and second floating gates: forming the dielectric layer on the first and second floating gates and the first insulation layer; and forming the second conductive layer on the dielectric layer.

In another embodiment, the method further comprises, before forming the first insulation layer, forming a second insulation layer on sides of the first and second floating gates facing each other.

In another embodiment, the method further comprises, before forming the first insulation layer: etching the tunnel oxide layer between the first and second floating gates to expose the substrate; and forming a second insulation layer on the exposed substrate and sides of the first and second floating gates facing each other.

In another embodiment, forming the first insulation layer is performed by forming a silicon nitride layer between the first and second floating gates and etching the silicon nitride layer to top faces of the first and second floating gates.

In another embodiment, exposing the top surfaces of the first and second floating gates is performed by isotropically etching the interlayer insulation layer with fluoric acid.

In another embodiment, the method further comprises, after forming the first conductive layer pattern, forming impurity regions in the active regions by using the hard mask pattern as an ion implantation mask.

In another aspect, the present invention is directed to a method for fabricating a nonvolatile memory device, comprising: forming first and second impurity regions in a substrate; forming a channel region between the first and second impurity regions; forming a tunnel oxide layer on the channel region; forming first and second floating gates on the tunnel oxide layer, the first and second floating gates being isolated from each other; forming an insulation layer between the first and second floating gates; forming a dielectric layer on the first and second floating gates and the insulation layer; and forming a control gate on the dielectric layer.

In one embodiment, a portion of the tunnel oxide layer is interposed between the first floating gate and the insulation layer.

In another embodiment, a portion of the tunnel oxide layer is interposed between the second floating gate and the insulation layer.

In another aspect, the present invention is directed to a nonvolatile memory device comprising: first and second impurity regions in a substrate; a channel region defined between the first and second impurity regions; a tunnel oxide layer on the channel region; first and second floating gates on the tunnel oxide layer, the first and second floating gates being isolated from each other; an insulation layer disposed between the first and second floating gates; a dielectric layer on the first and second floating gates and the insulation layer; and a control gate on the dielectric layer.

In one embodiment, a portion of the tunnel oxide layer is interposed between the first floating gate and the insulation layer.

In another embodiment, a portion of the tunnel oxide layer is interposed between the second floating gate and the insulation layer.

In another embodiment, at least one of the first and second floating gates is charged with electrons to make an off-state.

In another embodiment, a read operation is conducted with: applying a ground voltage to one of the impurity regions and applying a read voltage, which is higher than the ground voltage, to the other of the impurity regions; applying a control voltage, which is higher than an on-state's threshold voltage but lower than an off-state's threshold voltage, to the control gate; and applying the ground voltage, or a positive voltage higher than the ground voltage, to the substrate.

In another embodiment, wherein one of programming and erasing operations is conducted with: applying a ground voltage to the first and second impurity regions, and the substrate; and applying a control voltage to the control gate, whereby electrons are injected into the first and second floating gates from the channel region, or discharged into the channel region from the first and second floating gates, through an F-N tunneling effect.

In another embodiment, a programming operation is conducted with: applying a ground voltage to one of the impurity regions, and the substrate; applying a program voltage to the other of the impurity regions; and applying a control voltage to the control gate, whereby hot electrons are injected into the first and second floating gates from the channel region.

A further understanding of the nature and advantages of the inventions herein may be realized by reference to the remaining portions of the specification and the attached drawings.

### BRIEF DESCRIPTION OF THE DRAWINGS

The accompanying figures are included to provide a further understanding of the embodiments of the invention, and are incorporated in and constitute a part of this specification. The drawings illustrate example embodiments of the invention and, together with the description, serve to explain principles of the present invention. In the figures:

FIG. 1 is a sectional view showing a general cell gate structure in a stacked flash memory device of the nonvolatile memory device type;

FIGS. 2 through 11 are perspective views illustrating processing steps for fabricating a nonvolatile memory device in accordance with an embodiment of the invention;

FIGS. 12 through 18 are perspective views illustrating processing steps for fabricating a nonvolatile memory device in accordance with another embodiment of the invention;

FIGS. 19 through 21 are perspective views illustrating processing steps for fabricating a nonvolatile memory device in accordance with still another embodiment of the invention; and

FIG. 22 is a sectional view schematically showing a cell gate structure in the nonvolatile memory device in accordance with embodiments of the present specification, explaining an operation thereof.

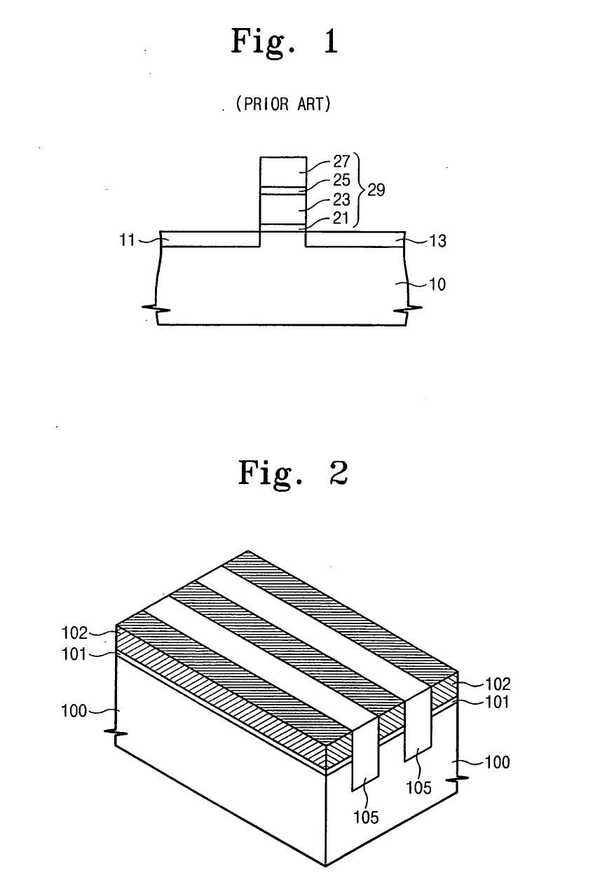

### DETAILED DESCRIPTION OF EMBODIMENTS OF THE INVENTION

Embodiments of the present invention will be described below in more detail with reference to the accompanying drawings. The present invention may, however, be embodied in different forms and should not be constructed as being limited to the embodiments set forth herein. Rather, these embodiments are provided so that this disclosure will be thorough and complete.

In the figures, the dimensions of layers and regions are exaggerated for clarity of illustration. It will also be understood that when a layer (or layer) is referred to as being ‘on’ another layer or substrate, it can be directly on the other layer or substrate, or intervening layers may also be present. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present.

In embodiments of the invention, the terms, ‘first’, ‘second’, and so forth, are used for discriminately describing floating gates, insulation layers, or conductive layers, distinguishing them from each other, but not in a restrictive manner.

Like reference numerals refer to like elements throughout this specification.

FIGS. 2 through 11 are perspective views illustrating processing steps for fabricating a nonvolatile memory device in accordance with an embodiment of the invention.

Referring to FIG. 2, after depositing a pad oxide layer 101 and a pad nitride layer 102 on a substrate 100, trenches (not shown) are formed in the substrate 100 by means of a photolithography process. After oxidizing inner sides of the trenches through a thermal process, the trenches are filled with an oxide. High-density plasma-enhanced chemical vapor deposition (HDP CVD) can, for example, be used for forming the oxide. By filling up the trenches by the oxide through the thermal oxidation process, this prevents impurities from infiltrating into the substrate 100.

A chemical-mechanical polishing (CMP) process is performed on the oxide to form the field isolation layers 105. Active regions are defined in the substrate between the trenches. During the CMP process, the pad nitride layer 102 operates as a polishing stopper. Such an operation of shallow trench isolation (STI) results in the formation of relatively narrow trenches. With smaller field isolation regions, integration density of the device is enhanced. While an STI technique is described above for forming the field isolation regions 105, other techniques re equally applicable to the present invention.

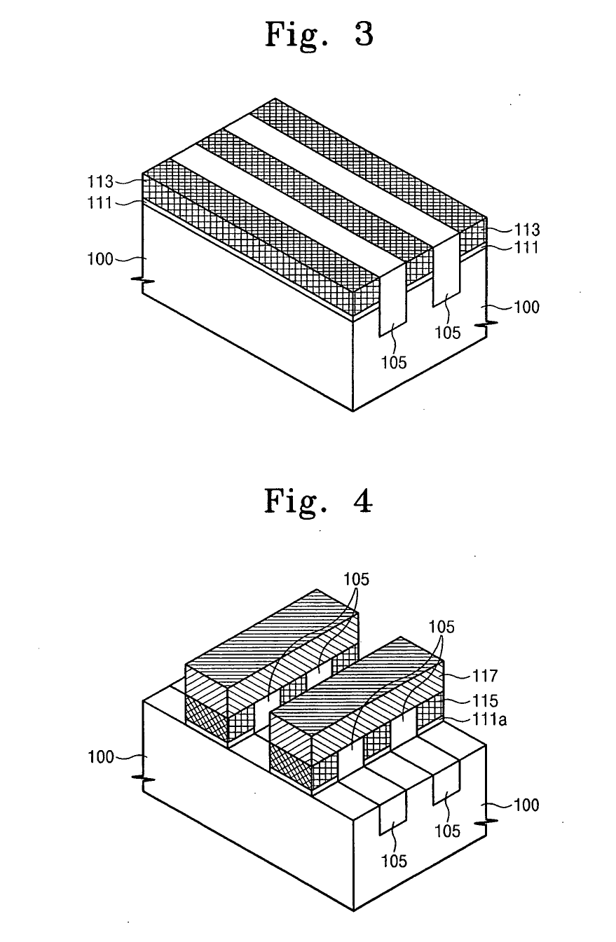

Next, referring to FIG. 3, the pad nitride layer 102 and the pad oxide layer 101, used in forming the field isolation layers 105, are removed therefrom and then a tunnel oxide layer 111 is deposited by means of thermal oxidation. The pad oxide layer 101 can be removed, for example, by a reactive dry etch using plasma, or by a wet etch using phosphoric acid. Here, the thermal oxidation process is conducted to form a thin and uniform silicon oxide (SiO₂) layer using heat after injecting oxygen and vapor into the substrate at the high temperature of 800˜1200° C. In an alternative embodiment, the pad oxide layer 101 can be retained and used as the tunnel oxide layer 111.

A first conductive layer 113 is then formed on the tunnel oxide layer 111, extending in a first direction. The first direction corresponds to a direction of extension of the active regions. The first conductive layer 113 may be formed, for example, by depositing doped polysilicon using CVD, and then performing a planarization process exposing the top faces of the field isolation layers 105.

Next, referring to FIG. 4, a hard mask pattern 117 is arranged on the substrate 100, intersecting adjacent portions of the first conductive layer 113 and extending in a second direction that is transverse, or perpendicular to, the first direction of extension of the first conductive layer 113. While the hard mask pattern 117 may intersect the first conductive layer 113 at an angle, it is preferred that they intersect perpendicularly. In one embodiment, the hard mask pattern 117 is formed of silicon nitride. Using the hard mask pattern 117 as an etch mask, the first conductive layer 113 is selectively etched away to form separated first conductive layer patterns 115. While forming the first conductive pattern 115, remnants of the tunnel oxide layer 111 under the first conductive layer 113 are likewise etched away to expose the top surface of the substrate 100. However, the portion of the tunnel oxide layer pattern 111a that lies under the first conductive layer pattern 115 remains thereon without being removed.

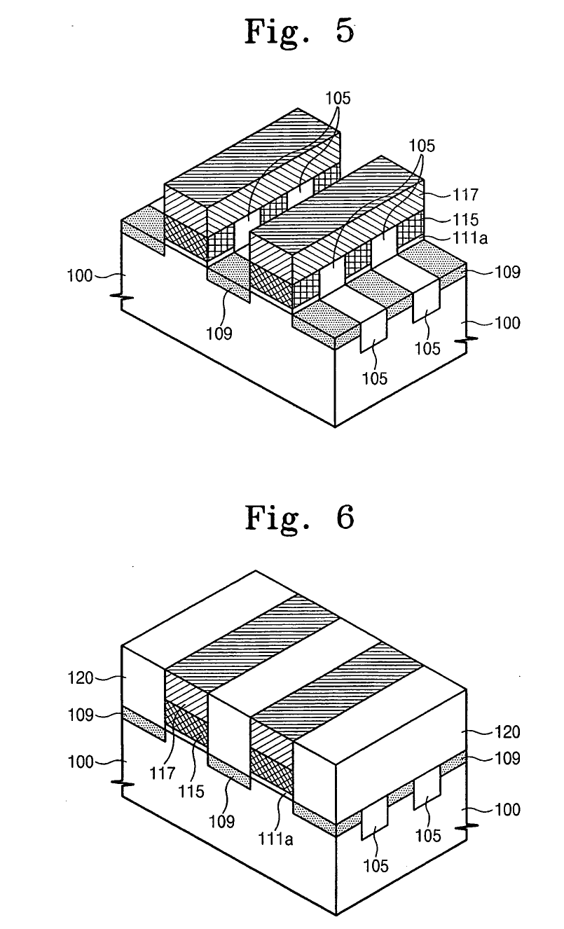

Thereafter, referring to FIG. 5, using the hard mask pattern 117 as an ion implantation mask, impurity regions 109 are formed in the substrate 100 for source/drain regions. A depth of the impurity regions 109 is adjusted by the level of the ion implantation energy.

Various wafer defects can be generated in the wafer following ion implantation, due to generation of defective lumps on lattices therein. Thus, a thermal operation may be conducted to the wafer in order to mitigate such defects.

Next, referring to FIG. 6, an interlayer insulation layer 120 is deposited on the exposed substrate 100 and the resulting structure. The interlayer insulation layer 120 can be formed, for example, by depositing an insulation layer through plasma-enhanced CVD (PECVD) and conducting planarization to expose the top surface of the hard mask pattern 117. The PECVD procedure is performed to form the insulation layer at a temperature less than 300° C., providing deposition speed faster than a normal CVD that utilizes a natural thermal reaction.

As only the hard mask pattern 117 is selectively removed during the subsequent processing steps, it is preferred that the interlayer insulation layer 120 is made of a material having an etch selectivity with respect to the hard mask pattern 117. Thus, in an embodiment where the hard mask pattern 117 is formed of silicon nitride, the interlayer insulation layer 120 can be formed of silicon oxide.

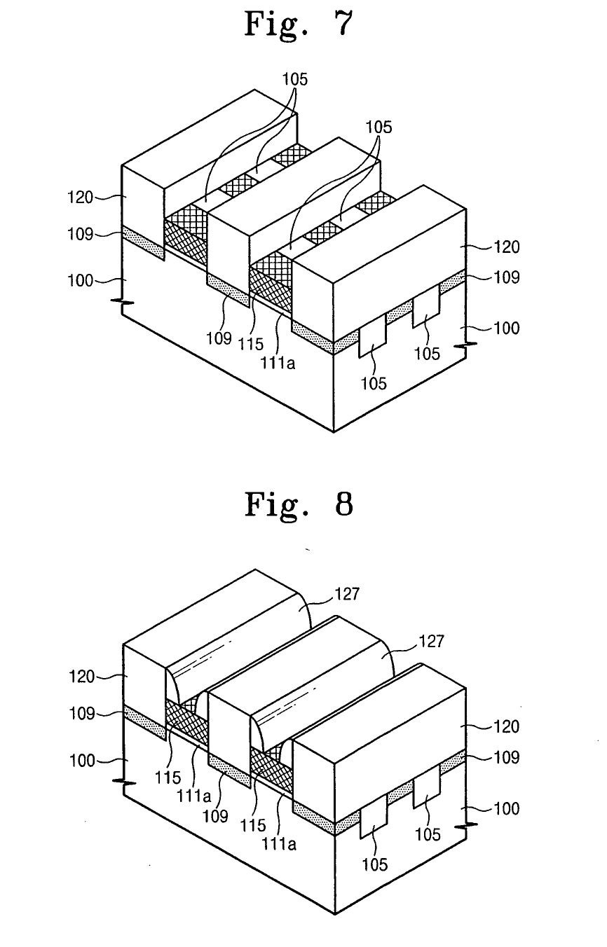

Referring to FIG. 7, the hard mask pattern 117 is selectively removed to expose the top face of the first conductive pattern 115 and the upper sidewalls of the interlayer insulation layer 120. The hard mask pattern 117 may be removed by a dry etch such as a reactive ion etch using plasma, or a wet etch using phosphoric acid.

Referring to FIG. 8, spacers 127 are then formed on the exposed sidewalls of the interlayer insulation layer 120. The spacers 127 can be formed by depositing a silicon nitride layer on the substrate 100, and by anisotropically etching the silicon nitride layer. Both edges of the first conductive pattern 115, which contact with the interlayer insulation layer 120, are covered by the spacers 127, but exposed is the center portion of the first conductive pattern 115.

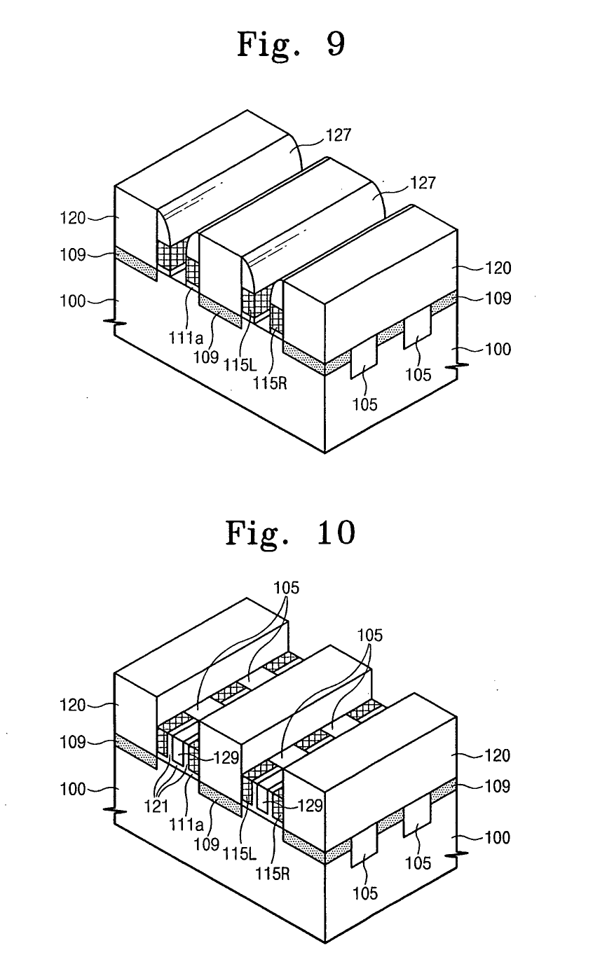

Next, referring to FIG. 9, using the spacers 127 as an etch mask, the first conductive pattern 115 is selectively etched to form first and second floating gates 115L and 115R that are isolated from each other in the first direction. While forming the first and second floating gates 115L and 115R, the tunnel oxide layer 111a under the first conductive pattern is also etched away to expose the upper surface of the substrate 100. However, the portions of the tunnel oxide layers 111a that lie under the first and second floating gates 115L and 115R remain thereon without being removed. During this procedure, the patterning operation can be carried out using a dry etch process.

Alternatively, the tunnel oxide layer 111a may optionally not be removed while etching the first conductive pattern 115.

Referring to FIG. 10, a first insulation layer 129 is then deposited between the first and second floating gates 115L and 115R. The first insulation layer 129 is provided to ensure physical isolation between the first and second floating gates, so it is preferred that it is formed at a minimum width. The first insulation layer 129 can be formed by providing a silicon nitride layer between the first and second floating gates 115L and 115R, and by partially removing the top portions of the silicon nitride layer. During this operation, the spacers 127 are likewise removed to expose the top surfaces of the first and second floating gates 115L and 115R. The silicon nitride layer and the spacers 127 can be removed, for example, by means of a wet etch using phosphoric acid, or a dry etch using plasma after conducting an etch-back operation on the deposited silicon nitride layer. While the first insulation layer 129 is illustrated as being at the same level as the first and second floating gates 115L and 115R, the first insulation layer 129 can optionally be excessively etched to a level that is slightly lower than the first and second floating gates 115L and 115R.

In addition, an optional second insulation layer 121 may be deposited on the exposed substrate 100 and sidewalls of the first and second floating gates 115L and 115R prior to formation of the first insulation layer 129. The second insulation layer 121 may be formed by means of thermal oxidation. Side faces of the tunnel oxide layer 111a contact the second insulation layer 121. The second insulation layer 121 contributes to cure defects or damage that has occurred on the sidewalls of the first and second floating gates 115L and 115R and the top surface of the substrate 100, as well as to reinforce the insulative operation of the first insulation layer 120.

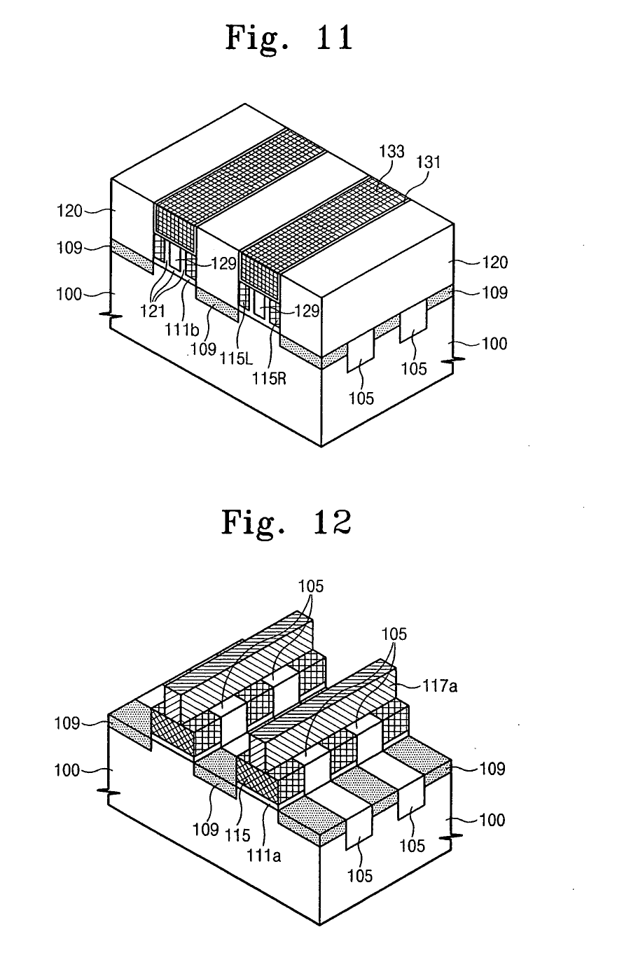

Next, referring to FIG. 11, a dielectric layer 131 and a second conductive layer 133 are sequentially deposited on the first and second floating gates 115L and 115R between the patterns of the interlayer insulation layer 120, the first insulation layer 129, and the second insulation layer 121. In one exemplary embodiment, the dielectric layer 131 is formed of an oxide/nitride/oxide (ONO) layer. The dielectric layer 131 may be formed, for example, by means of CVD or atomic layer deposition (ALD). ALD is advantageous for deposition of the dielectric layer 131 accurately and at a relatively small thickness; however, deposition time can be longer than CVD.

The second conductive layer 133 is formed by depositing doped polysilicon, metal, or silicide, and by conducting planarization to expose the interlayer insulation layer 120. Optionally, the second conductive layer 133 may be configured in a structure with metals or silicide materials stacked on a polysilicon layer. Since the second conductive layer 133 is used as a control gate to which a signal voltage is applied to activate the memory cell, it is preferred that it be comprised of a material with low resistance.

By employing a split floating gate structure, as opposed to a single floating gate structure, although charge can leak out from one of the floating gates in a unit memory cell, it is possible to retain data of the unit cell owing to the other of the floating gates. Therefore, the performance of data storage in a memory cell is enhanced to raise the reliability of the nonvolatile memory device.

FIGS. 12 through 18 are perspective views illustrating processing steps for fabricating a nonvolatile memory device in accordance with another embodiment of the invention. In this embodiment, the processing steps of FIG. 2 through FIG. 5 of the above embodiment are the same for the present embodiment.

Referring to FIG. 12, the hard mask pattern 117a is etched in a pull-back process to be smaller in width than its original width. This etching process, as a type of pull-back, may be carried out with an isotropic dry etch using phosphoric acid. The pull-back process with phosphoric acid is advantageous to precisely control the amount of width reduction of the hard mask pattern 117a. As a result, the first conductive pattern 115 is partially exposed at both sides of the shrunken-down hard mask pattern 117a.

Next, referring to FIG. 13, an interlayer insulation layer 119 is deposited on the substrate 100. The interlayer insulation layer 119 may be formed by depositing a silicon oxide layer through PECVD and then performing planarization to expose the top faces of the hard mask pattern 117a.

Since only the hard mask pattern 117a is selectively removed in the subsequent processing step, the interlayer insulation layer 119 is preferred to be made of a material having an etch selectivity relative to the hard mask pattern 117a. Thus, when the hard mask pattern 117 is made of silicon nitride, the interlayer insulation layer 119 may be formed of silicon oxide.

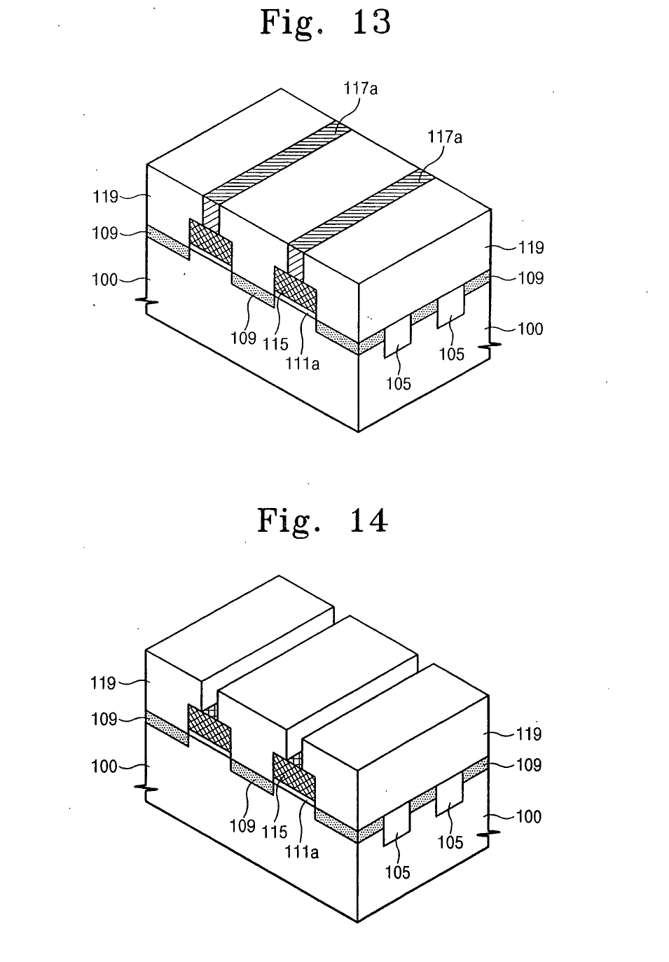

Referring to FIG. 14, the hard mask pattern 117a is then selectively removed to expose the center top faces of the first conductive pattern 115. The hard mask pattern 117 may be removed by a reactive dry etch using plasma, or a wet etch using phosphoric acid.

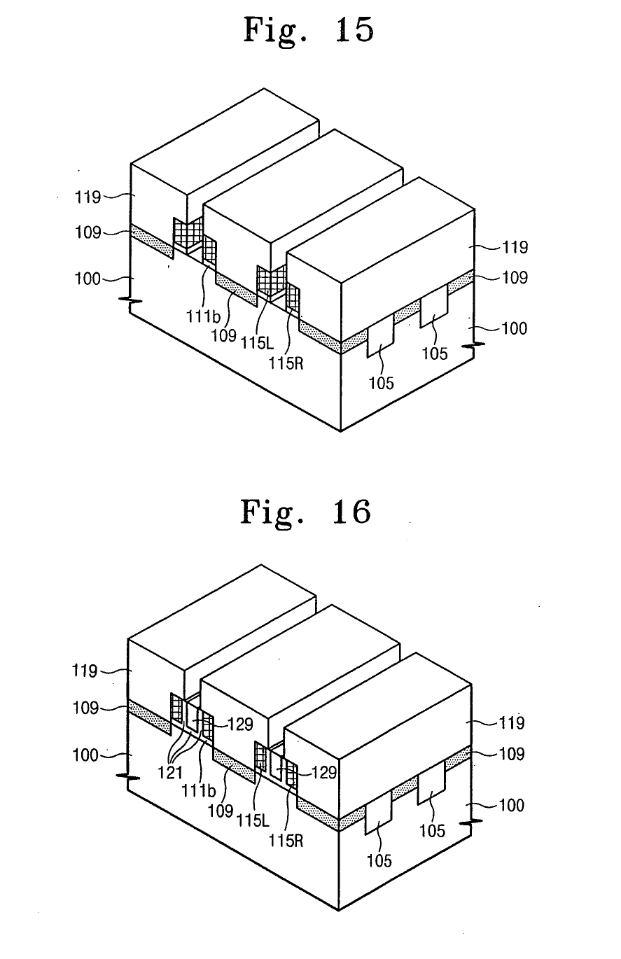

Referring to FIG. 15, using the interlayer insulation layer 119 as an etch mask, the first conductive pattern 115 is selectively etched to form the first and second floating gates 115L and 115R that are isolated from each other along the first direction. The interlayer insulation layer 119 can be formed, for example, of silicon oxide. As silicon has higher etch selectivity against a silicon oxide layer than against a nitride layer, the first and second floating gates 115L and 115R can be patterned with high precision, and the first conductive layer pattern 115 can be smoothly etched. While etching the first conductive layer pattern 115, the tunnel oxide layer 111a under the first conductive pattern 115 is likewise etched away to expose the upper surface of the substrate 100. However, the tunnel oxide layer 111b under the first and second floating gates 115L and 115R remains therein without being removed. The etching process can be performed by a dry etch procedure using plasma. Optionally, the tunnel oxide layer 111a can remain following etching of the first conductive layer pattern 115.

Referring to FIG. 16, between the first and second floating gates 115L and 115R the first insulation layer 129 is next deposited. The first insulation layer 129 may be provided by depositing a silicon nitride layer between the first and second floating gates 115L and 115R, and by removing an upper portion of the silicon nitride layer by means of a phosphoric acid etch. While the first insulation layer 129 is illustrated as being level with the first and second floating gates 115L and 115R, the first insulation layer 129 may be excessively etched to have a level that is slightly lower than the first and second floating gates 115L and 115R.

As described above, optionally, a second insulation layer 121 may be more formed prior to depositing the first insulation layer 129, on the exposed surfaces of the substrate 100 and the sidewalls of the first and second floating gates 115L and 115R. The second insulation layer 121 may be formed through thermal oxidation. The second insulation layer 121 contacts the exposed side faces of the tunnel oxide layer 111b.

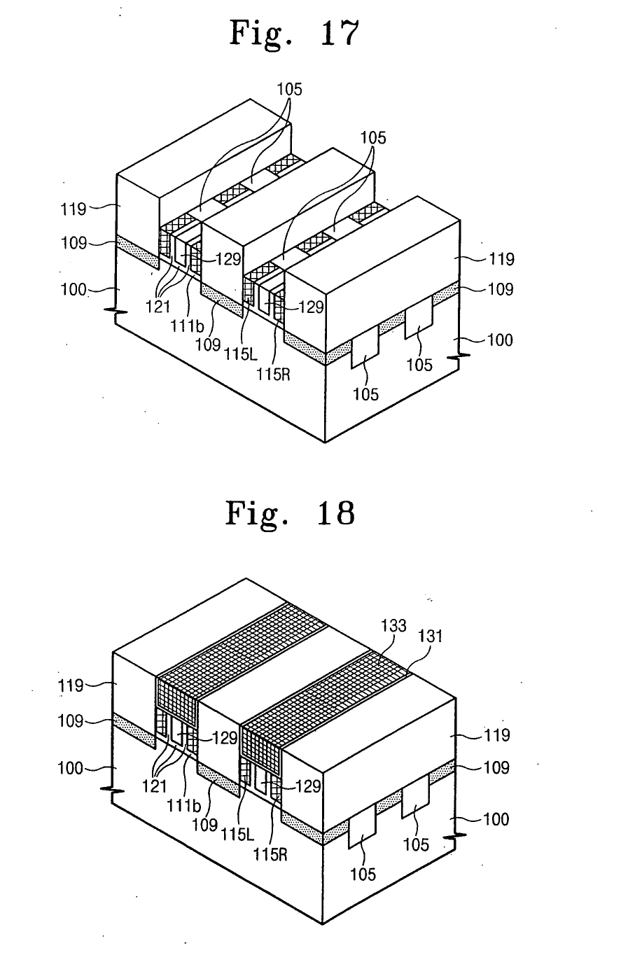

Referring to FIG. 17, the interlayer insulation layer 119 is then selectively etched to expose the top surfaces of the first and second floating gates 115L and 115R at both sides of the etched interlayer insulation layer 120. An isotropic etching operation can be conducted for this operation using fluoric acid.

Although not shown, the interlayer insulation layer 119 becomes lower in height during this procedure because the isotropic etch can remove both the top and side portions of the interlayer insulation layer 119. Considering this, the hard mask pattern 117 of FIG. 4 can be formed to a higher level so that the resulting interlayer insulation layer is of sufficient height.

Referring to FIG. 18, the dielectric layer 131 and the second conductive layer 133 are then sequentially deposited on the first and second floating gates 115L and 115R between the patterns of the interlayer insulation layer 120, the first insulation layer 129, and the second insulation layer 121. The dielectric layer 131 may be formed of an oxide/nitride/oxide (ONO) layer. The second conductive layer 133 can be formed by depositing doped polysilicon, metal, or silicide, and by conducting planarization to expose the interlayer insulation layer 120. in another embodiment, the second conductive layer 133 can comprise a multi-layered structure with metals or silicide materials stacked on a polysilicon layer.

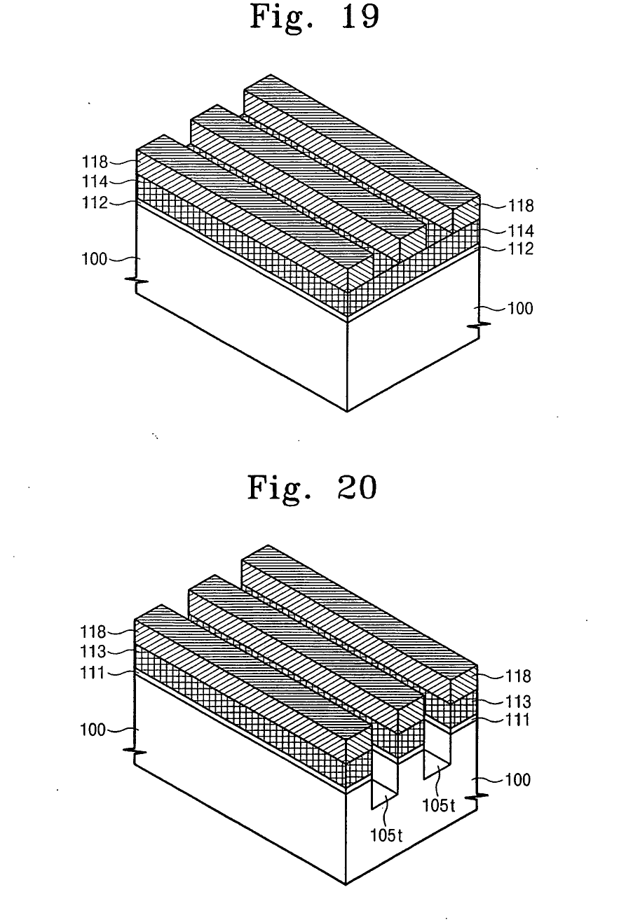

FIGS. 19 through 21 are perspective views illustrating processing steps for fabricating a nonvolatile memory device in accordance with still another embodiment of the invention.

First, referring to FIG. 19, an oxide layer 112, a conductive layer 114, and a hard mask pattern 118 are formed on the substrate 100 in sequence.

Next, referring to FIG. 20, using the hard mask pattern 118 as an etch mask, the conductive layer 114, the oxide layer 112, and the substrate 100 are selectively etched to form trenches 105t. The conductive layer 114 and the oxide layer 112 are patterned to be the first conductive layer 113 and the tunnel oxide layer 111 as described above in connection with the above embodiments.

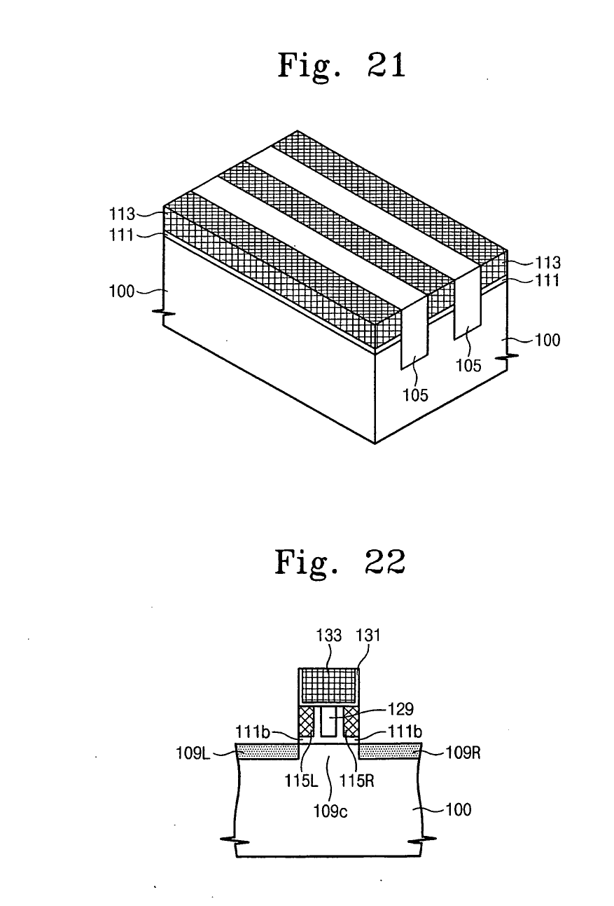

Referring to FIG. 21, after filling the trenches 105t with oxide, a process of planarization is performed to expose the top surfaces of the first conductive layer 113, resulting in the field isolation layers 105.

In this embodiment, the processing steps used for forming the first conductive layer 113 are different than the aforementioned embodiments; however, the subsequent steps may be as same.

FIG. 22 is a sectional view schematically illustrating a cell gate structure in a nonvolatile memory device in accordance with embodiments of the present specification, explaining the operation thereof.

Referring to FIG. 22, the first and second impurity regions 109L and 109R are disposed in the substrate 100. Between the first and second impurity regions 109L and 109R is placed a channel region 109C. The first and second floating gates 115L and 115R are located over the channel region 109C, with the tunnel oxide layer 111b interposed therebetween. The control gate 133 is placed over the first and second floating gates 115L and 115R, with the dielectric layer 131 interposed therebetween. The first and second floating gates 115L and 115R are electrically and physically isolated from each other by the first insulation layer 129.

Programming data in the nonvolatile memory device may mean injecting electrons into the floating gate of the memory cell. To the contrary, erasing data may mean releasing electrons from the floating gate into the channel region. On the other hand, holes move in the reverse directions during programming and erasing. Further, programming data corresponds with a condition of increasing the threshold voltage of the memory cell, while erasing data corresponds with a condition of decreasing the threshold voltage of the memory cell. A programmed memory cell can be referred to as off-cell, while an erased memory cell can be referred to as on-cell. For convenience in description, it is assumed that the threshold voltage of an off-cell is about 3V and the threshold voltage of an on-cell is about −3V.

As an illustrative example, the operation of a N-channel memory cell with respect to the motion of electrons will now be described, in connection with the embodiments of the present specification.

In programming and erasing operations of the nonvolatile memory device, a high voltage, e.g., 10 through 20V, is applied to the control gate 133 so as to cause electrons to be injected into the split floating gates 115L and 115R from the channel region through the tunnel oxide layer 111b. The first and second impurity regions 109L and 109R and the substrate 100 are supplied with a ground voltage 0V. Accordingly, a conductive channel is generated in the channel region 109C, enabling electrons to penetrate the tunnel oxide layer 111b and to be injected into the first and second floating gates 115L and 115R. Then, the first and second floating gates 115L and 115R are set in a programmed state at the same time, i.e., an off-state. As a result, the first and second floating gates 115L and 115R are charged up to a threshold voltage of about 3V.

By inversing the polarity of the voltage applied to the control gate 133, e.g., if the control gate 133 is supplied with a voltage of −20 through −10V, the electrons injected into the first and second floating gates 115L and 115R are forced to be discharged therefrom into the channel region 109C. As a result, the first and second floating gates 115L and 115R are placed simultaneously in an erased state, i.e., an on-state. As a result, the first and second floating gates 115L and 115R are set to a threshold voltage of about −3V.

In another embodiment, the programming operation may optionally be accomplished by hot electron injection, and not by the tunneling effect as aforementioned. In this embodiment, first, the ground voltage is applied to the first impurity region 1109L and the substrate 100, while a program voltage of 3.5 through 5.5V is applied to the second impurity region 109R. A voltage of 4.5 through 6V is applied to the control gate 133. Accordingly, the conductive channel is conditioned in pinch-off state under the second floating gate 150R and hot electrons generated therein are injected into the second floating gate 150R over a potential barrier of the tunnel oxide layer 111b, forcing the second floating gate 150R to be set in a programmed state, i.e., an off-state. The ground voltage is applied to the second impurity region 109R and the substrate 100, while the program voltage is applied to the first impurity region 109L. The voltage of 4.5 through 6V is applied to the control gate 133. Then, hot electrons generated therein are injected into the first floating gate 150L over the potential barrier of the tunnel oxide layer 111b, forcing the first floating gate 150L to be set in a programmed state, i.e., an off-state. The order of injecting the hot electrons into the first and second floating gates 115L and 115R can optionally be reversed.

In a read operation of the nonvolatile memory device, the first impurity region 109L is supplied with the ground voltage while the second impurity region 109R is supplied with a read voltage (e.g., 0 5˜1.5V) that is higher than the ground voltage. The substrate 100 is supplied with the ground voltage or a low positive voltage (e.g., 0.3˜0.5V) that is higher than the ground voltage. The control gate 133 is supplied with a voltage higher than the on-cell's threshold voltage but lower than the off-cell's threshold voltage, e.g., the ground voltage. During this, channel current is not present because the channel region under the first and second floating gates 115L and 115R which remain in the off-state is in a condition of high resistance. Thus, the memory cell is read as an off-cell.

If electrons flow out into the first impurity region 109L from the first floating gate 115L, this reduces the threshold voltage of the first floating gate 115L. Thereby, the channel region under the first floating gate 115L is in a condition of low resistance and not high resistance. Thus, even though the ground voltage 0V is applied to the control gate 133, the channel region under the first floating gate 115L becomes conductive to generate a current. However, the second floating gate 115R from which electrons do not flow out still retains its threshold voltage of about 3V and the channel region under the second floating gate 115R is also conditioned in high resistance, so that a current cannot flow therethrough. To the contrary, although electrons flow out from the second floating gate 115R, the memory cell is read as an off-cell unless there is no flow of electrons from the first floating gate 115L.

As such, the two split floating gates contribute to enhancing the capacity of data storage and the operational reliability of the nonvolatile memory device.

Additionally, as the nonvolatile memory device fabricated according to the illustrative embodiments of the specification has the structure of a multi-bit cell structure, it is permissible for the present invention to be applicable with a nonvolatile memory device of the multi-bit cell structure.

As described above, with the structure of the split floating gates in a single memory cell, although charge can leak out from one of the floating gates in a unit memory cell, it is possible to retain data of the unit cell owing to the other of the floating gates. Therefore, the performance of data storage in a memory cell is enhanced to raise the reliability of the nonvolatile memory device.

The above-disclosed subject matter is to be considered illustrative, and not restrictive, and the appended claims are intended to cover all such modifications, enhancements, and other embodiments, which fall within the true spirit and scope of the present invention. Thus, the scope of the present invention is to be determined by the broadest permissible interpretation of the following claims and their equivalents, and shall not be restricted or limited by the foregoing detailed description.

What is claimed is:

1. A method for fabricating a nonvolatile memory device, comprising:
forming a first conductive layer on an active region between field isolation layers in a substrate, a tunnel oxide layer being interposed between the substrate and the first conductive layer, extending along a first direction;
forming a hard mask pattern that intersects the first conductive layer on the substrate and extends along a second direction;
forming a first conductive layer pattern having pattern portions that are separated from each other in the first direction using the hard mask pattern as an etch mask;
removing a central part of the first conductive layer pattern portions to form first and second floating gates that are separated from each other in the first direction; and
forming a second conductive layer on the first and second floating gates, a dielectric layer being interposed between the first and second floating gates and the second conductive layer.

2. The method as set forth in claim 1, wherein forming the first and second floating gates comprises:
forming an interlayer insulation layer on the substrate including the first conductive layer pattern and planarizing the interlayer insulation layer to expose an top face of the hard mask pattern;
removing the hard mask pattern to expose an top face of the first conductive layer pattern and sidewalls of the interlayer insulation layer;
forming spacers on the exposed sidewalls of the interlayer insulation layer; and
etching the first conductive layer pattern by using the spacers as an etch mask.

3. The method as set forth in claim 2, wherein the interlayer insulation layer is formed of a material having an etch selectivity with respect to the hard mask pattern.

4. The method as set forth in claim 2, wherein forming the second conductive layer comprises:
forming a first insulation layer to fill a space between the first and second floating gates;
forming the dielectric layer on the first and second floating gates and the first insulation layer; and
forming the second conductive layer on the dielectric layer.

5. The method as set forth in claim 4, further comprising, before forming the first insulation layer, forming a second insulation layer on sides of the first and second floating gates facing each other.

6. The method as set forth in claim 4, further comprising, before forming the first insulation layer:
etching the tunnel oxide layer between the first and second floating gates to expose the substrate; and
forming a second insulation layer on the exposed substrate and the sides of the first and second floating gates facing each other.

7. The method as set forth in claim 4, wherein forming the first insulation layer is performed by forming a silicon nitride layer between the first and second floating gates and etching the silicon nitride layer and the spacers to top surfaces of the first and second floating gates.

8. The method as set forth in claim 1, wherein forming the first and second floating gates comprises:
etching the hard mask pattern to reduce a width of the hard mask pattern down in width and exposing a part of a top face of the first conductive layer pattern at both sides of the hard mask pattern;
forming and flattening an interlayer insulation layer on the substrate to expose a top face of the reduced-width hard mask pattern;
removing the reduced-width hard mask pattern to expose a top face of the first conductive layer pattern; and
etching the first conductive layer pattern by using the interlayer insulation layer as an etch mask.

9. The method as set forth in claim 8, wherein the interlayer insulation layer is formed of a material having an etch selectivity with respect to the hard mask pattern.

10. The method as set forth in claim 8, wherein forming the second conductive layer comprises:
forming a first insulation layer to fill a space between the first and second floating gates;
exposing top surfaces of the first and second floating gates:
forming the dielectric layer on the first and second floating gates and the first insulation layer; and
forming the second conductive layer on the dielectric layer.

11. The method as set forth in claim 10, further comprising, before forming the first insulation layer, forming a second insulation layer on sides of the first and second floating gates facing each other.

12. The method as set forth in claim 10, further comprising, before forming the first insulation layer:
etching the tunnel oxide layer between the first and second floating gates to expose the substrate; and
forming a second insulation layer on the exposed substrate and sides of the first and second floating gates facing each other.

13. The method as set forth in claim 10, wherein forming the first insulation layer is performed by forming a silicon nitride layer between the first and second floating gates and etching the silicon nitride layer to top faces of the first and second floating gates.

14. The method as set forth in claim 10, wherein exposing the top faces of the first and second floating gates is performed by isotropically etching the interlayer insulation layer with fluoric acid.

15. The method as set forth in claim 1, further comprising, after forming the first conductive layer pattern, forming impurity regions in the active regions by using the hard mask pattern as an ion implantation mask.

16. A method for fabricating a nonvolatile memory device, comprising:
forming first and second impurity regions in a substrate;
forming a channel region between the first and second impurity regions;
forming a tunnel oxide layer on the channel region;
forming first and second floating gates on the tunnel oxide layer, the first and second floating gates being isolated from each other;
forming an insulation layer between the first and second floating gates;
forming a dielectric layer on the first and second floating gates and the insulation layer; and
forming a control gate on the dielectric layer.

17. The method as set forth in claim 16, wherein a portion of the tunnel oxide layer is interposed between the first floating gate and the insulation layer.

18. The method as set forth in claim 16, wherein a portion of the tunnel oxide layer is interposed between the second floating gate and the insulation layer.

19. A nonvolatile memory device comprising:
first and second impurity regions in a substrate;
a channel region defined between the first and second impurity regions;
a tunnel oxide layer on the channel region;
first and second floating gates on the tunnel oxide layer, the first and second floating gates being isolated from each other;
an insulation layer disposed between the first and second floating gates;
a dielectric layer on the first and second floating gates and the insulation layer; and
a control gate on the dielectric layer.

20. The nonvolatile memory device as set forth in claim 19, wherein a portion of the tunnel oxide layer is interposed between the first floating gate and the insulation layer.

21. The nonvolatile memory device as set forth in claim 19, wherein a portion of the tunnel oxide layer is interposed between the second floating gate and the insulation layer.

22. The nonvolatile memory device as set forth in claim 19, wherein at least one of the first and second floating gates is charged with electrons to make an off-state.

23. The nonvolatile memory device as set forth in claim 19, wherein a read operation is conducted by:
applying a ground voltage to one of the impurity regions and applying a read voltage, which is higher than the ground voltage, to the other of the impurity regions;
applying a control voltage, which is higher than an on-state's threshold voltage but lower than an off-state's threshold voltage, to the control gate; and
applying the ground voltage, or a positive voltage higher than the ground voltage, to the substrate.

24. The nonvolatile memory device as set forth in claim 19, wherein one of programming and erasing operations is conducted by:
applying a ground voltage to the first and second impurity regions, and the substrate; and
applying a control voltage to the control gate,
whereby electrons are injected into the first and second floating gates from the channel region, or discharged into the channel region from the first and second floating gates, through an F-N tunneling effect.

25. The nonvolatile memory device as set forth in claim 19, wherein a programming operation is conducted by:
applying a ground voltage to one of the impurity regions, and the substrate;
applying a program voltage to the other of the impurity regions; and
applying a control voltage to the control gate,
whereby hot electrons are injected into the first and second floating gates from the channel region.
